(19) United States
(12) Patent Application Publication
(10) Pub. No.: US 2018/0006581 A1
(43) Pub. Date: Jan. 4, 2018

(54) VOLTAGE CONVERTING DEVICE AND WIRELESS POWER TRANSMITTING DEVICE

(71) Applicant: Kabushiki Kaisha Toshiba, Tokyo (JP)

(72) Inventor: Hiroaki Ishihara, Yokohama (JP)

(73) Assignee: Kabushiki Kaisha Toshiba, Tokyo (JP)

(21) Appl. No.: 15/702,386

(22) Filed: Sep. 12, 2017

Related U.S. Application Data
(63) Continuation of application No. PCT/JP2015/074570, filed on Aug. 31, 2015.

(51) Int. Cl. H02M 7/5387; H02J 50/12; G01R 25/00; H02M 1/00

(52) U.S. Cl. CPC H02M 7/53871; H02M 1/00; H02J 50/12; G01R 25/00; H02M 2001/0009

(57) ABSTRACT

According to one embodiment, a voltage converting device includes a DC power source; an inverter generating AC power; an AC component detector configured to detect an AC component of current flowing through a first terminal or a second terminal of the inverter in the DC power source side; and a phase estimator configured to estimate a phase relation between a phase of voltage of the AC power and a phase of current of the AC power based on an amplitude of a specific frequency component contained in a first absolute value signal of the AC component. The AC power generated by the inverter is supplied to a loading device, and an impedance of the loading device at a fundamental of a driving frequency of the inverter is smaller than an impedance of the loading device at an odd-order harmonic of the driving frequency.

### CROSS-REFERENCE TO RELATED APPLICATIONS

The present application is a Continuation of International Application No. PCT/JP2015/074570, filed on Aug. 31, 2015, the entire contents of which is hereby incorporated by reference.

### FIELD

Embodiments described herein relate to a voltage converting device and a wireless power transmitting device.

### BACKGROUND

In wireless power transmission, it is known that a transmitting efficiency of power is increased as a phase difference between AC voltage and AC current on a power transmission side becomes closer to 0, that is, as a power factor becomes higher. There is proposed a method in which voltage and current are detected, and a phase difference is detected using an exclusive OR of periods during which the voltage and the current lie within a predetermined range, respectively.

However, in the above method, a location to detect the current is at an AC voltage output terminal, and thus voltage at an observation location fluctuates steeply. In particular, an application to transmit high power generally needs a high output voltage, and thus a range of voltage fluctuations becomes large. In such a condition, it is difficult to secure a precision of detecting the current.

For example, using a current sensor generally involves a spike-like noise that is mixed in the current sensor at the time when voltage varies. Although there is a method in which a resistor having a very low resistance is inserted, and current is observed from voltage between both ends of the resistor. However, even by such a method, it is difficult to remove an influence of the voltage fluctuations completely.

In a case of detecting a period during which current lies within a predetermined range, as with the above method, an erroneous detection of the current reaching the predetermined range is made due to a spike-like noise, a detection precision of a phase difference between current and voltage declines.

In addition, it is difficult to fully equalize a frequency characteristics of current detecting means and a frequency characteristics of voltage detecting means. If there is a phase difference in input-output characteristics between the voltage detecting means and the current detecting means at a frequency to be detected, the phase difference causes an error. In general, in particular, as a frequency increases, an influence of a phase characteristics becomes noticeable.

### BRIEF DESCRIPTION OF THE DRAWINGS

FIG. 1 is a simplified equivalent circuit diagram of a typical wireless power transmitting device;

FIG. 2A and FIG. 2B are graphs illustrating relations between power factor and efficiency in the wireless power transmitting device having a configuration illustrated in FIG. 1;

FIG. 3 is a diagram illustrating a configuration of a voltage converting device according to a first embodiment;

FIG. 4 is a graph illustrating an inverter output voltage waveform;

FIG. 5 is a graph illustrating an inverter output voltage waveform of a time when a duty is decreased;

FIG. 6 is a graph illustrating an inverter output voltage waveform of a time when a single-phase inverter is used;

FIG. 7A and FIG. 7B are graphs each illustrating an absolute value of an impedance in the configuration illustrated in FIG. 1 when viewed from a power transmission side;

FIG. 8A and FIG. 8B are graphs each illustrating a voltage waveform and a current waveform in an inverter output;

FIG. 9A and FIG. 9B are graphs each illustrating a voltage waveform and a current waveform in an inverter input;

FIG. 10A and FIG. 10B are graphs each illustrating an output waveform of a high-pass filter;

FIG. 11A and FIG. 11B are graphs each illustrating an output waveform of an absolute value detector;

FIG. 12 is a graph illustrating amplitudes of frequency components in the output waveform of the absolute value detector at phase differences of 0 degrees and 90 degrees;

FIG. 13 is a graph illustrating a relation between a phase difference and an amplitude of a second-harmonic frequency component of a fundamental in the output waveform of the absolute value detector;

FIG. 14 is a diagram illustrating a configuration example of a phase difference estimator;

FIG. 15 is a diagram illustrating a specific configuration example of the phase difference estimator illustrated in FIG. 14;

FIG. 16 is a diagram illustrating a specific example of the absolute value detector;

FIG. 17 is a diagram illustrating a configuration of a phase difference estimator according to a second embodiment;

FIG. 18 is a graph illustrating a relation between a phase difference and a DC component in the output waveform of the absolute value detector;

FIG. 19 is a diagram illustrating a configuration of a phase difference estimator according to a third embodiment;

FIG. 20 is a graph illustrating a relation between a phase difference and a ratio between a second-harmonic wave component of a fundamental frequency and the DC component in the output waveform of the absolute value detector;

FIG. 21 is a diagram illustrating a configuration of a voltage converting device according to a fourth embodiment;

FIG. 22 is a diagram illustrating a configuration of a voltage converting device according to a fifth embodiment;

FIG. 23 is a diagram illustrating another configuration of a voltage converting device according to the fifth embodiment;

FIG. 24 is a diagram illustrating still another configuration of a voltage converting device according to the fifth embodiment;

FIG. 25 is a diagram illustrating a configuration of a voltage converting device according to a sixth embodiment;

FIG. 26 is a chart illustrating an example of an operation flow according to the sixth embodiment;

FIG. 27 is a diagram illustrating another configuration of a voltage converting device according to the sixth embodiment; and

FIG. 28 is a diagram illustrating a configuration of a voltage converting device according to a seventh embodiment.

### DETAILED DESCRIPTION

According to one embodiment, a voltage converting device includes: a DC power source; an inverter; an AC component detector; a phase estimator.

The DC power source is configured to generate direct-current voltage

The inverter includes a first terminal electrically connected to one of a positive-side terminal and a negative-side terminal of the DC power source and including a second terminal electrically connected to another one of the positive-side terminal and the negative-side terminal, the inverter being configured to generate AC power based on the direct-current voltage.

The AC component detector is configured to detect an AC component of current flowing through the first terminal or the second terminal.

The phase estimator is configured to estimate a phase relation between a phase of voltage of the AC power and a phase of current of the AC power based on an amplitude of a specific frequency component contained in a first absolute value signal of the AC component.

The AC power generated by the inverter is supplied to a loading device.

An impedance of the loading device at a fundamental of a driving frequency of the inverter is smaller than an impedance of the loading device at an odd-order harmonic of the driving frequency.

Embodiments of the present invention will be described below with reference to the drawings.

### First Embodiment

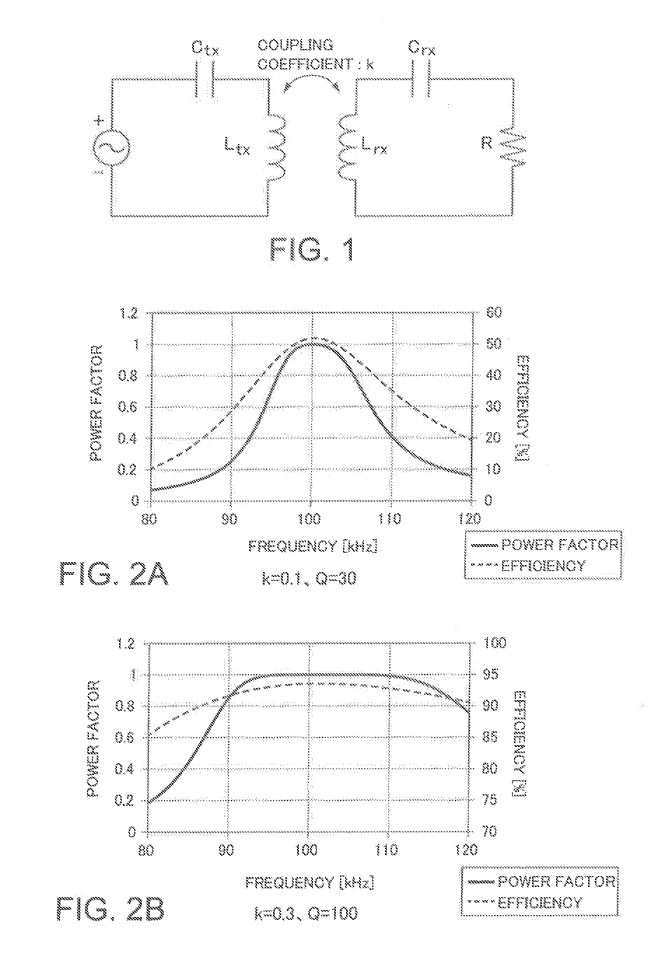

FIG. 1 illustrates an equivalent circuit having a simplified configuration of a typical wireless power transmitting device. The wireless power transmitting device illustrated in FIG. 1 includes an AC power supply, a power transmitting coil Lₜₓ, and a power transmission side capacitance Cₜₓ on a power transmission side, and a power receiving coil Lᵣₓ, and a power reception side capacitance Cᵣₓ on a power reception side, and a load resistor R.

The power transmitting coil Lₜₓ and the power transmission side capacitance Cₜₓ on the power transmission side constitute a series resonant circuit. The resonance frequency of this circuit is given as follows.

$${f}_{tx} = \frac{1}{2 π \sqrt{{L}_{tx} {C}_{tx}}} [ Hz ] \qquad ( 1 )$$

Similarly, the inductor Lᵣₓ and the capacitance Cᵣₓ on the power reception side also constitute a series resonant circuit, the resonance frequency of which is given as follows.

$${f}_{rx} = \frac{1}{2 π \sqrt{{L}_{rx} {C}_{rx}}} [ Hz ] \qquad ( 2 )$$

FIG. 2A illustrates a relation between frequency of the AC power supply on the power transmission side and power transmitting efficiency (hereinafter, simply referred to as efficiency) of a time when resonance frequencies fₜₓ and fᵣₓ are set at 100 kHz, and a relation between frequency of the AC power supply of the power transmission side and power factor of an output of the AC power supply. FIG. 2A illustrates characteristics of the wireless power transmitting device of a time when a coupling coefficient k are set at 0.1, and Q values of the coils Lₜₓ and Lᵣₓ at 100 kHz are both set at 30. The AC power supply on the power transmission side is assumed to be an ideal AC voltage source, the inductances of Lₜₓ and Lᵣₓ are both set at 100 μH, and the load resistor is set to meet conditions on which a maximum efficiency at an AC power supply frequency of 100 kHz.

FIG. 2B illustrates characteristics of the wireless power transmitting device of a time when a coupling coefficient k is 0.3, and Q values of the coils Lₜₓ and Lᵣₓ at 100 kHz are both set at 100. The other conditions are the same as those for FIG. 2A.

As seen from the above, the characteristics vary in accordance with the coupling coefficient, the Q values of the coils, and other factors. However, in both of the cases, a frequency at which the power factor takes its maximum value and a frequency at which the efficiency takes its maximum value substantially agree, and it can be said that the higher the power factor is, the higher the transmitting efficiency is.

The power factor is defined as a ratio of active power to apparent power. In a case of an AC power supply that outputs voltage and current of an ideal sinusoidal wave, the power factor can be expressed as follows,

λ=cos(φ) (3)

where φ denotes a difference between the phase of an output voltage and a phase of an output current. That is, the power factor takes the maximum value being one when a phase difference between the voltage and the current is zero. The phase difference φ is defined as the phase of the current with reference to the voltage.

Here, it has been described that the efficiency can be increased in the wireless power transmitting device illustrated in FIG. 1 by increasing the power factor. It can be easily supposed that, even in a case of adding various modifications such as addition of a rectifying circuit and addition of a filter circuit, improvement of the efficiency can be expected in many cases by increasing the power factor in the wireless power transmission.

As described above, a power factor is a ratio of active power to apparent power. In general, an element used in a power circuit has a rated voltage and a rated current, beyond which the element cannot be operated. An increase in the power factor means an increase in a ratio that active power accounts for of apparent power. Therefore, it can be said that improving the power factor allows the power circuit to handle more power than power circuits having the same ratings. From these respects, for wireless power transmission, as well as various applications using an AC power supply. It can be said that the power factor of the AC power supply output is one of important properties.

One of features of the present embodiment is to make it easy, in a case of using an inverter as an AC power supply, a phase difference between a power factor of an output of the inverter, namely, a phase difference between voltage and current of the output of the inverter.

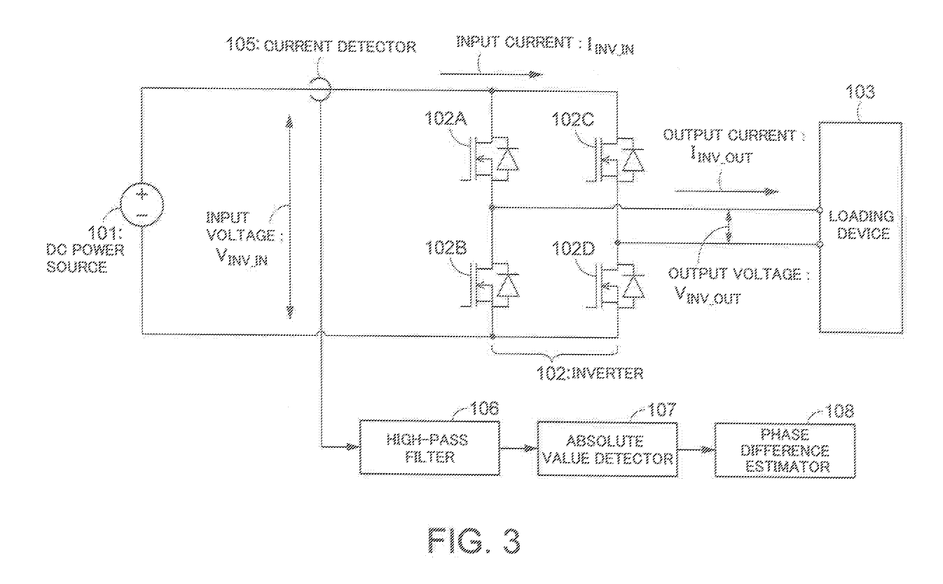

FIG. 3 illustrates a voltage converting device according to a first embodiment. The voltage converting device includes a DC power source 101 configured to output direct-current voltage, an inverter 102, a current detector 105, a high-pass filter 106, an absolute value detector 107, and a phase difference estimator 108. The combination of the current detector 105 and the high-pass filter 106 corresponds to an AC component detector configured to detect an AC component of an input current of the inverter 102.

An input voltage of the inverter 102 is defined as V_{INV}_{_}_{IN}, and an input current thereof is defined as I_{INV}_{_}_{IN}. In addition, an output voltage of the inverter 102 is defined as V_{INV}_{_}_{OUT}, and an output current thereof is defined as I_{INV}_{_}_{OUT}. To the output of the inverter 102, a loading device 103 is connected. The loading device 103 refers to the whole load driven by the inverter 102. For example, in the typical wireless power transmitting device illustrated in FIG. 1, the loading device includes all of the capacitance Cₜₓ and the power transmitting coil Lₜₓ the power transmission side that are connected to the output of the AC power supply, the power reception side capacitance Cᵣₓ and the power receiving coil Lᵣₓ on the power reception side, and the load resistor R. The combination of the capacitance Cₜₓ and the power transmitting coil Lₜₓ on the power transmission side forms a coil unit on the power transmission side. The combination of the power reception side capacitance Cᵣₓ and the power receiving coil Lᵣₓ on the power reception side forms a coil unit on the power reception side.

The inverter 102 includes a first terminal electrically connected to one of a positive-side terminal and a negative-side terminal of the DC power source 101, and a second terminal electrically connected to the other of the positive-side terminal and the negative-side terminal, and is configured to generate AC power (AC voltage and AC current) based on an input DC voltage from the DC power source 101. That is, the inverter 102 operates as a DC-AC converter. The inverter 102 includes four switching elements 102A, 102B, 103C, and 104D, and is configured to generate the above AC power by switching these switching elements in accordance with a switching signal supplied from a driving device. The AC power generated by the inverter 102 is supplied to the loading device 103.

Here, each of the switching elements is formed by a transistor and a diode that are reversely connected in parallel. Being reversely connected in parallel means that directions in which currents flowing in the connected elements are reversed (the currents flow backward into the DC power source). One ends of the switching elements 102A and 102B are connected to each other, and one ends of the switching elements 102C and 102D are connected to each other. The other ends of the switching elements 102A and 102C are both connected to a power source terminal (positive-side terminal) of the DC power source 101. The other ends of the switching elements 102B and 102D are both connected to a ground terminal (negative-side terminal) of the DC power source 101. A connection node between the switching elements 102A and 102B is connected to one of two input terminals of the loading device 103. A connection node between the switching elements 102C and 102D is connected to the other one of the two input terminals. The inverter 102 controls the switching elements using a switching signal supplied from the driving device (not illustrated).

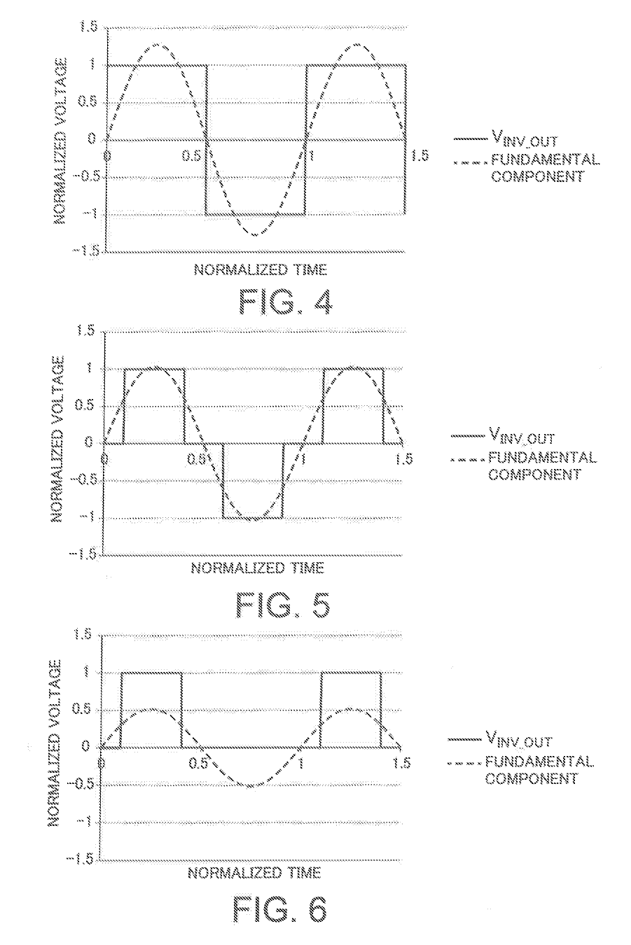

FIG. 4 illustrates a voltage waveform of an inverter output. The ordinate is normalized using an input DC voltage, and the abscissa is normalized using a period T. Also in voltage waveform diagrams described hereinafter, values similarly normalized are used. The voltage waveform of the inverter output is a square wave having a period corresponding to an inverter driving frequency. Such a square wave contains a frequency component of f_{fund}=1/T [Hz] and odd-multiple harmonic components of f_{fund}, with respect to the period T. Hereinafter, f_{fund} will be referred to as a fundamental frequency. In addition, a component of the frequency f_{fund} contained in voltage, current, or both of them will be referred to as a fundamental component. FIG. 4 also illustrates a fundamental component contained in the voltage waveform of the square wave. As seen from the graph, a waveform of the fundamental component is a sinusoidal wave including zero crossing points (points at which the voltage is zero) that coincide with transition timings of the square wave.

Now, methods for reducing an amplitude of an AC voltage while keeping a direct-current voltage of an input include a method for changing a duty of a square wave. FIG. 5 illustrates a voltage waveform and a fundamental component of a time when a duty is changed. The fundamental component is a sinusoidal wave that decreases in amplitude with a decrease in duty and crosses zero at a middle point of a time period during which the voltage waveform runs on zero (voltage is zero). Methods for decreasing the duty include a method in which a dead time is inserted between drive signals for a U phase and a V phase of a differential inverter, a method in which phases of the drive signals for the U phase and the V phase are shifted from each other, and other methods. Here, the U phase refers to a section formed by the switching elements 102A and 102B in the inverter 102, and the V phase refers to a section formed by the switching elements 102C and 102D in the inverter 102.

The present embodiment is applicable to common AC power supply generating devices that generate AC outputs containing fundamental components from their DC voltage input. For example, in a case of a single phase inverter, an output voltage is constituted by a DC component and an AC component, and as illustrated in FIG. 6, an output voltage of a single phase inverter contains a fundamental component. Therefore, the present embodiment is applicable to single phase inverters.

A magnitude of an inverter output current with respect to an amplitude of an inverter output voltage is determined in accordance with an impedance of a loading device. When an absolute value of the impedance at a fundamental frequency is low, a fundamental component of the inverter output current is large, and when the absolute value is high, the fundamental component of the output current is small. Similarly, magnitudes of currents each containing an odd-multiple harmonic component of the fundamental frequency are also determined in accordance with absolute values of the impedance at a frequency of each component. Here, when the impedance of the loading device at the fundamental frequency is lower than an impedance of the loading device at an odd-multiple harmonic, a frequency component contained in the inverter output current mainly includes the fundamental component only. At this point, a waveform of the current is close to a sinusoidal wave of the fundamental frequency. It can be said this is because the loading device selectively operates as a filter that lets only a fundamental component of frequency components in an inverter output voltage pass the filter.

A difference between a phase of a fundamental component of the inverter output current and a phase of a fundamental component of the inverter output voltage is defined as a fundamental phase difference. Letting the fundamental phase difference denote φ, “λ” obtained by the above expression (3) is defined as a fundamental power factor. The fundamental phase difference is determined using a phase component of the impedance at the fundamental frequency. When the phase component of the impedance at the fundamental frequency is zero, that is, an imaginary part of the impedance is zero, the fundamental power factor takes its maximum value being one. As mentioned before, when the loading device operates as a filter to odd-order harmonics (disallows the harmonics to pass), the current is close to a sinusoidal wave having the fundamental frequency. Therefore, a component that contributes to an output power of the inverter is mainly a fundamental component only. For this reason, it can be said that detecting the fundamental power factor is substantially equivalent to detecting a power factor of an output of the inverter. In addition, it can be said that detecting the fundamental phase difference is substantially equivalent to detecting a phase difference between voltage and current of an inverter output.

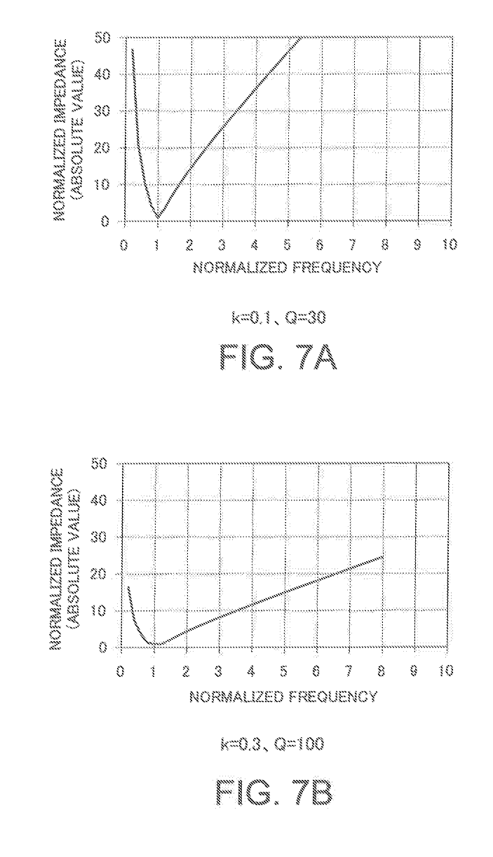

As an example, FIG. 7A and FIG. 7B illustrate a frequency characteristics of the absolute value of the impedance that is estimated from the output of the AC power supply in the wireless power transmitting device illustrated in FIG. 1. FIG. 7A illustrates a frequency characteristics in a case where k=0.1 and Q=30, and FIG. 7B illustrates a frequency characteristics in a case where k=0.3 and Q=100. As seen from the graphs, in the configuration illustrated in FIG. 1, the impedances take their local minimum values at about the fundamental component. Therefore, it can be said that the fundamental component is selectively allowed to pass.

The present embodiment provides a method for detecting, in a case where a loading device operates as a filter that lets a fundamental component pass the filter, a fundamental power factor, namely a phase difference between voltage and current of a fundamental component (fundamental phase difference).

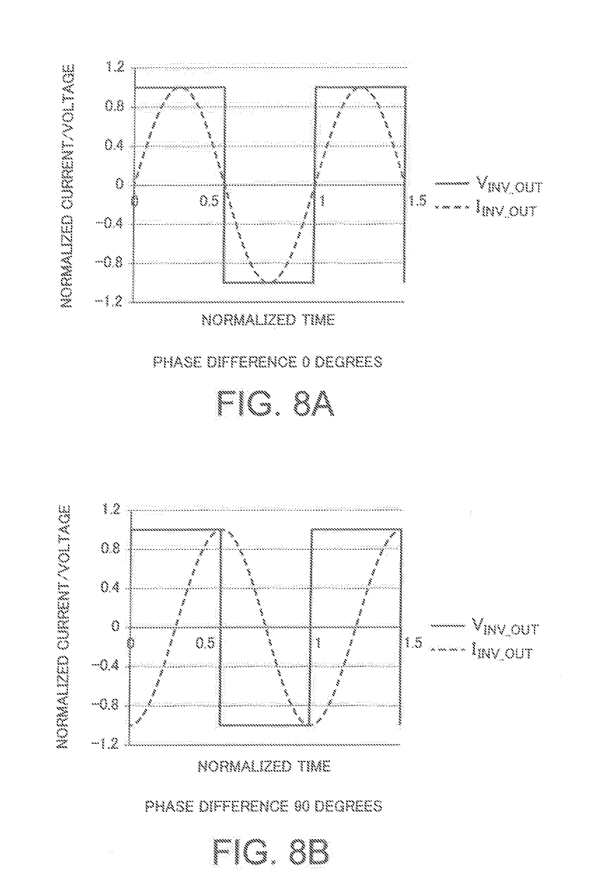

FIG. 8A illustrates waveforms of an input voltage and an input current of an inverter of a time when a phase difference between an output current of the inverter and an output voltage of the inverter is 0 degrees, that is, when the fundamental power factor is one. In addition, as another typical example, FIG. 8B illustrates waveforms of a time when the phase difference between the input voltage and the input current is 90 degrees, that is, when the fundamental power factor is 0. The ordinate of the currents illustrated in FIG. 8A and FIG. 8B represents values of the currents normalized by amplitudes of the currents. Also in current waveform diagrams described hereinafter, current values similarly normalized are used.

In FIG. 3, the current detector 105 is configured to detect inverter input current. As mentioned above, the inverter 102 is electrically connected to the positive-side terminal of the DC power source 101 at one of its terminals and electrically connected to the negative-side terminal at the other terminal. Here, the current detector 105 is configured to detect current that flows through the terminal of the inverter 102 connected to the positive-side terminal. However, the current detector 105 can be configured to detect current that flows through the terminal of the inverter 102 connected to the negative-side terminal.

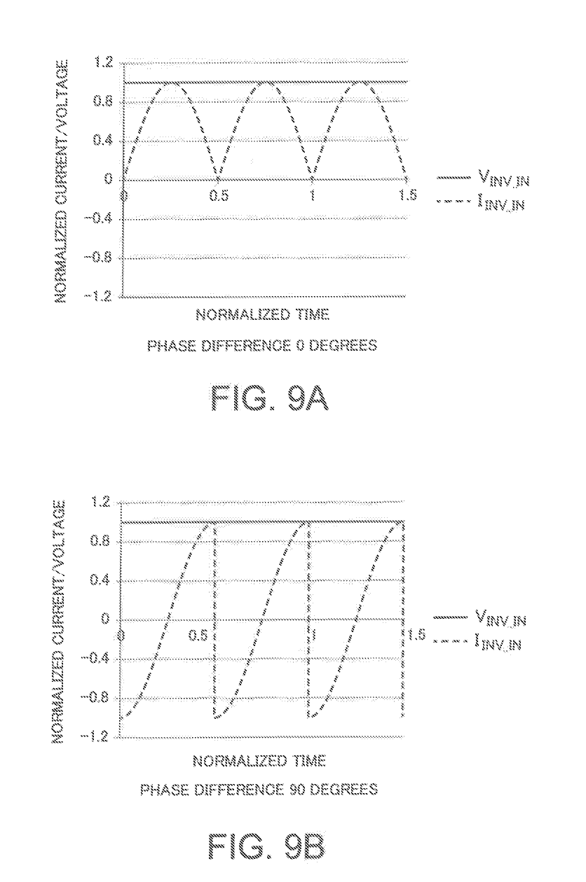

When viewed from the input of the inverter 102, the switching elements 102A to 102D of the inverter 102 switch a current path every half cycle of the fundamental frequency. Therefore, an observed current is a sinusoidal inverter output current that is reversed every half cycle of an inverter driving frequency. FIG. 9A and FIG. 9B illustrates observed currents. That is, obtained waveforms are sinusoidal waves multiplied by a square wave of the inverter output voltage. FIG. 9A corresponds to a case where the phase difference is 0 degrees, and FIG. 9B corresponds to a case where the phase difference is 90 degrees. A voltage waveform at the input of the inverter is DC and constant.

The current detected by the current detector 105 is input into the high-pass filter 106. The high-pass filter 106 is configured to remove a DC component from the input signal. Since the waveform of the inverter input current is, as mentioned above, a sinusoidal wave multiplied by a square wave, the waveform is a periodic waveform having half the period of the fundamental frequency. Such a periodic waveform contains a DC component and even-order harmonic components of the fundamental frequency. A component having the lowest frequency next to the DC component is a second-harmonic frequency of the fundamental frequency, and the high-pass filter 106 operates to let a component of this frequency (component of the second-harmonic frequency) and components of frequencies higher than the second-harmonic frequency pass the high-pass filter 106. This prevents the DC component from passing the high-pass filter 106 (removes the DC component). Here, the inverter input current contains higher, even-order harmonic components of the fundamental frequency, but their contribution becomes less significant as their frequencies become higher. Thus, it suffices to let components of frequencies up to a frequency to the extent that a required precision is secured pass in subsequent computation. Therefore, the high-pass filter 106 may be replaced by a band-pass filter having an appropriate passband. In a case of the band-pass filter, a cutoff frequency on a high frequency side can be determined based on a required estimation precision of phase difference.

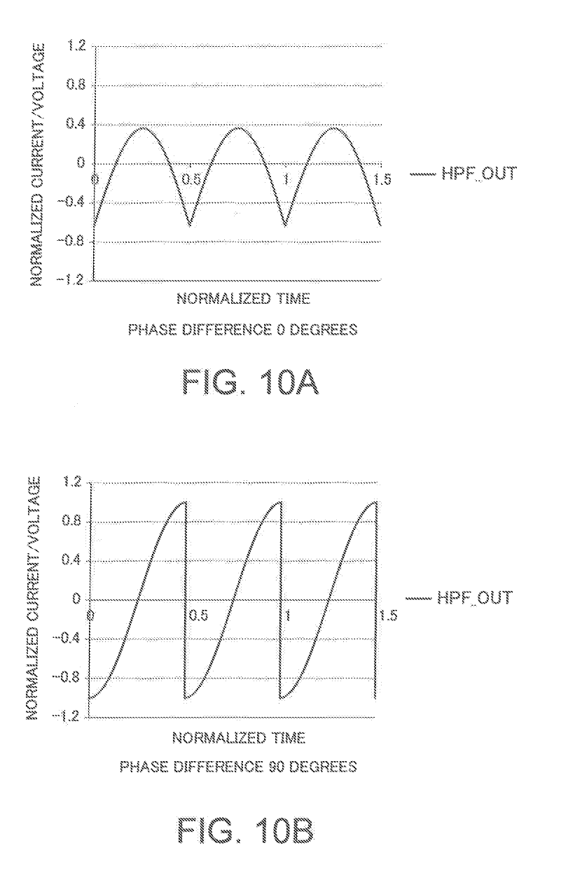

An output waveform of the high-pass filter that is an input current waveform of the inverter 102 from which a DC component is removed by the high-pass filter 106, is defined as “HPF_OUT”. HPF_OUT is illustrated in FIG. 10A and FIG. 10B. FIG. 10A corresponds to a case where the phase difference is 0 degrees, and FIG. 10B corresponds to a case where the phase difference is 90 degrees. An output of the high-pass filter 106 is input into the absolute value detector 107.

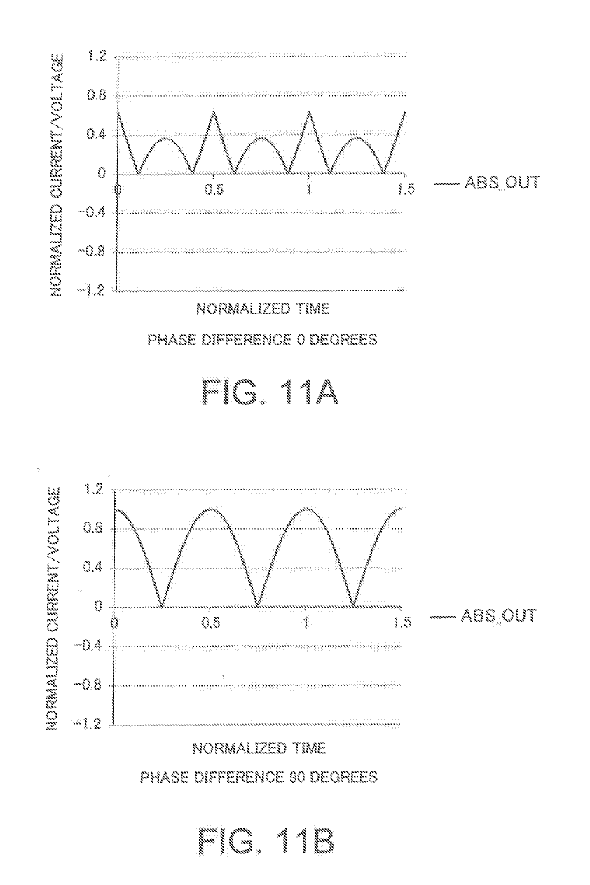

The absolute value detector 107 is configured to generate an absolute value signal that represents an absolute value of an input signal of the absolute value detector 107. An output waveform of the absolute value detector 107 is defined as “ABS_OUT”. ABS_OUT is illustrated in FIG. 11A and FIG. 11B. FIG. 11A corresponds to a case where the phase difference is 0 degrees, and FIG. 11B corresponds to a case where the phase difference is 90 degrees.

An output of the absolute value detector 107 is input into the phase difference estimator 108. The phase difference estimator 108 is configured to estimate a phase difference from the absolute value signal that is the output of the absolute value detector 107. A method for this will be described below in detail.

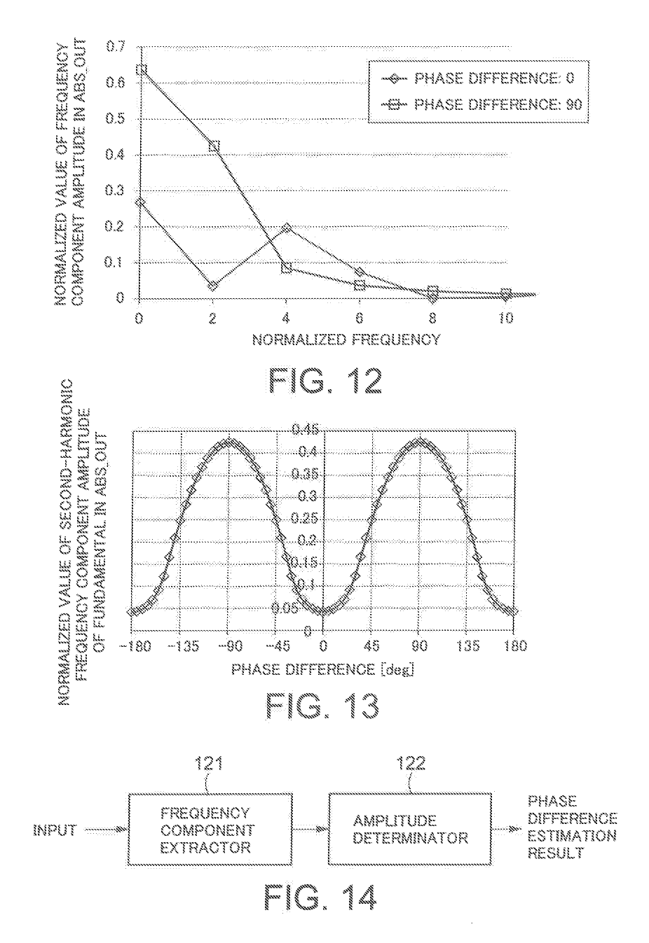

The waveforms illustrated in FIG. 11A and FIG. 11B (output waveforms of the absolute value detector 107) are subjected to the Fourier transformation to calculate components of frequencies, the results of which are illustrated in FIG. 12. The abscissa of FIG. 12 is normalized by the fundamental frequency. ABS_OUTs (the output waveforms of the absolute value detector 107) illustrated in FIG. 11A and FIG. 11B are repeating waveforms having a period being half the period of the fundamental frequency, irrespective of their phase differences. Thus, frequency components contained in ABS_OUT are even-order harmonics of the fundamental, namely, 2×n×f_{fund} (n=0, 1, 2, . . . ). The sign × represents multiplication. The ordinate is a value normalized by an amplitude of the inverter output current.

From FIG. 12, it is understood that amplitudes significantly differs among frequency components between the case where the phase difference is 0 degrees and the case where the phase difference is 90 degrees.

In FIG. 12, focus attention on second-harmonic frequency components of the fundamental as an example. When the phase difference of 0 degrees, the second-harmonic frequency component of the fundamental has a very large value in comparison to when the phase difference is 90 degrees. This result provides a prediction that a value of a second-harmonic frequency component of a fundamental contained in ABS_OUT (the output waveform of the absolute value detector 107) significantly varies in accordance with the phase difference. FIG. 13 illustrates a result of calculating a magnitude of the second-harmonic frequency component of the fundamental in ABS_OUT of a time when the phase difference of the inverter output current to the inverter output voltage is varied from −180 degrees to 180 degrees, assuming that the inverter output current is an ideal sinusoidal wave. From FIG. 13, it is understood that the second-harmonic frequency component of the fundamental takes its minimum value at phase differences of 0 degrees, 180 degrees, and −180 degrees and takes its maximum value at a phase differences of −90 degrees and 90 degrees.

For example, when the phase difference lies within a range from −90 degrees to 90 degrees, it can be said that the phase difference between voltage and current becomes small as the second-harmonic frequency component of the fundamental in ABS_OUT (the output waveform of the absolute value detector 107) becomes small. Utilizing this relation, the phase difference can be estimated using an amplitude of the second-harmonic frequency component of the fundamental in ABS_OUT as a specific frequency component.

A case where the phase difference lies within a range from −180 degrees to −90 degrees and a range from 90 degrees to 180 degrees is equivalent to a case where an output power of the inverter 102 is negative, namely, a case where power is input into the inverter 102. In a case where the voltage converting device is configured in such a manner that a flow of the power is limited to one direction, and that the power is reliably output from the inverter 102, the phase difference should lie within a range from −90 degrees to 90 degrees. In such a case, it can be said that the phase difference comes close to zero, namely, the phase difference becomes small as a content of a second-harmonic wave becomes small.

In a case of applying the present embodiment to a system in which the flow of the power is bidirectional, namely, the system involving a case where power is output from an inverter and a case where power is input into the inverter, the phase difference may be estimated by combination use with a direction in which the power flows. That is, the phase difference may be determined to lie within a range from −90 degrees to 90 degrees when the power is output, and the phase difference may be determined to lie within a range from −180 degrees to −90 degrees or a range from 90 degrees to 180 degrees. In this case, when the power is output, a second-harmonic wave output becomes small as the phase difference comes close to 0 degrees, and when the power is input, the second-harmonic wave output becomes large as the phase difference comes closer to 0 degrees.

Furthermore, by combination use with an additional method of roughly detecting the phase difference between voltage and current, the phase difference may be estimated with more precision. Within each of limited ranges from −180 degrees to −90 degrees, −90 degrees to 0 degrees, 0 degrees to 90 degrees, and 90 degrees to 180 degrees, the amplitude of the second-harmonic frequency component of the fundamental in ABS_OUT (the output waveform of the absolute value detector) illustrated in FIG. 13 takes a unique value in accordance with the phase difference, and in the ranges other than the each limited range, there are phase differences at which the amplitude takes the same value. Determination may be made as to only within which of these four ranges the phase difference lies, by roughly defecting the phase difference. Specific examples of this method include a method of monitoring voltage and current of the inverter output, whereby the phase difference can be roughly detected. From the result of this and the second-harmonic wave component of the fundamental in ABS_OUT (the output waveform of the absolute value detector) in the configuration illustrated in FIG. 13, the phase difference can be estimated with more precision. In a case where the range of the phase difference is limited, such as a case where the flow of the power 1s limited to one direction, the voltage converting device may be configured in such a manner that the phase difference can be roughly determined within only the range.

As described above, in the case of using the second-harmonic frequency component of the fundamental frequency in ABS_OUT (the output waveform of the absolute value detector), the phase difference estimator 108 can have any configuration that has a function of extracting a second-harmonic frequency component and a function of determining an amplitude of the second-harmonic frequency component. FIG. 14 illustrates an example of a configuration of the phase difference estimator 108. The phase difference estimator 108 includes a frequency component extractor 121 and an amplitude determinator 122. The frequency component extractor 121 is configured to extract a second-harmonic frequency component from ABS_OUT (the output waveform of the absolute value detector). The amplitude determinator 122 is configured to estimate a phase difference in accordance with the amplitude of the extracted second-harmonic frequency component (performs amplitude determination).

Methods of extracting a second-harmonic frequency component with the frequency component extractor 121 include a use of a band-pass filter or a high-pass filter for an analog signal. Alternatively, sampling on a certain cycle and the Fourier transformation may be performed.

The amplitude determination by the amplitude determinator 122 may be performed by determining whether the amplitude lies within a predetermined range, so as to determine whether the phase difference lies within a predetermined range. Alternatively, determination may be made as to whether the phase difference is close to a predetermined value by determining whether the amplitude is smaller or larger than a certain threshold value. For example, when the phase difference lies within a range from −90 degrees to 90 degrees, whether the phase difference is close to zero can be determined by determining whether the amplitude the detected second-harmonic frequency component is close to zero (the threshold value). As an example, in a case where an absolute value difference between the value of the amplitude and the threshold value is less than a certain value, the phase difference can be determined to be close to zero. Alternatively, in a case where the phase difference lies within a specified range (e.g., a range from −90 degrees to 90 degrees), the phase difference may be uniquely estimated from the value of the amplitude. As long as the amplitude is used to estimate the phase difference, use may be made of methods other than the method described here.

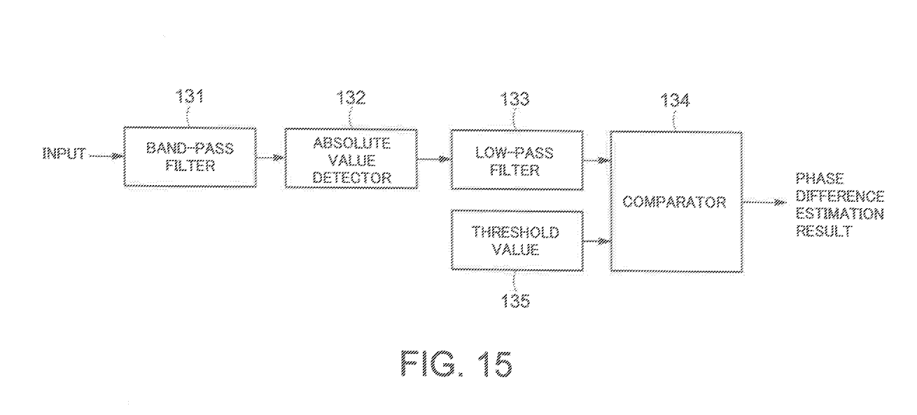

FIG. 15 illustrates a more specific example of the phase difference estimator 108 illustrated in FIG. 14. The phase difference estimator 108 includes a band-pass filter 131, an absolute value detector 132, a low-pass filter 133, a comparator 134, and a threshold value storage 135. The threshold value storage 135 may be a memory, a magnetic storage device such as a hard disk, or an optical storage device such as an optical disk. The memory may be a volatile memory such as an SRAM and a DRAM, or a nonvolatile memory such as a NAND, FeRAM, MRAM, and ROM.

The band-pass filter 131 is configured to extract the second-harmonic frequency component of the fundamental. The absolute value detector 132 is configured to calculate, from the extracted second-harmonic frequency component of the fundamental, an absolute value signal that represents an absolute value of the second-harmonic frequency component. The low-pass filter 133 is configured to let a low-frequency component (a signal of a DC component) of this absolute value signal pass the low-pass filter 133. The comparator 134 is configured to compare an amplitude of a signal that passes the low-pass filter 133 with at least one of threshold values that are read from the threshold value storage 135. The phase relation between voltage and current is thereby detected in a form of whether the phase difference lies within the predetermined range, whether the phase difference is close to the predetermined value, the phase difference itself, or the like.

A plurality of threshold values may be stored in the threshold value storage 135, and the comparator 134 may determine within which range of the plurality of ranges the phase difference lies, based on comparison with the plurality of threshold values. Alternatively, using a look-up table in which values of DC components and phase relations are associated with each other, the phase relation may be acquired from the value of the DC component extracted by the low-pass filter 133 and the look-up table. The threshold values, the values set in the look-up table, or both of them can be determined based on the aforementioned relation illustrated in FIG. 13. With the configuration illustrated in FIG. 15, since what is input into the comparator 134 is the DC component (a DC signal), use can be made of a very-slow comparator. Alternatively, an output signal of the low-pass filter 133 may be converted into a digital data by an analog to digital converter (ADC) (i.e., the value of the DC component may be acquired), and the comparator 134 may compare the value of the DC component (the digital data) with the threshold value. This allows the comparator 134 to be implemented using a digital circuit. In this case, the ADC can be slow, and thus improvement of the precision and reduction of power consumption can be expected.

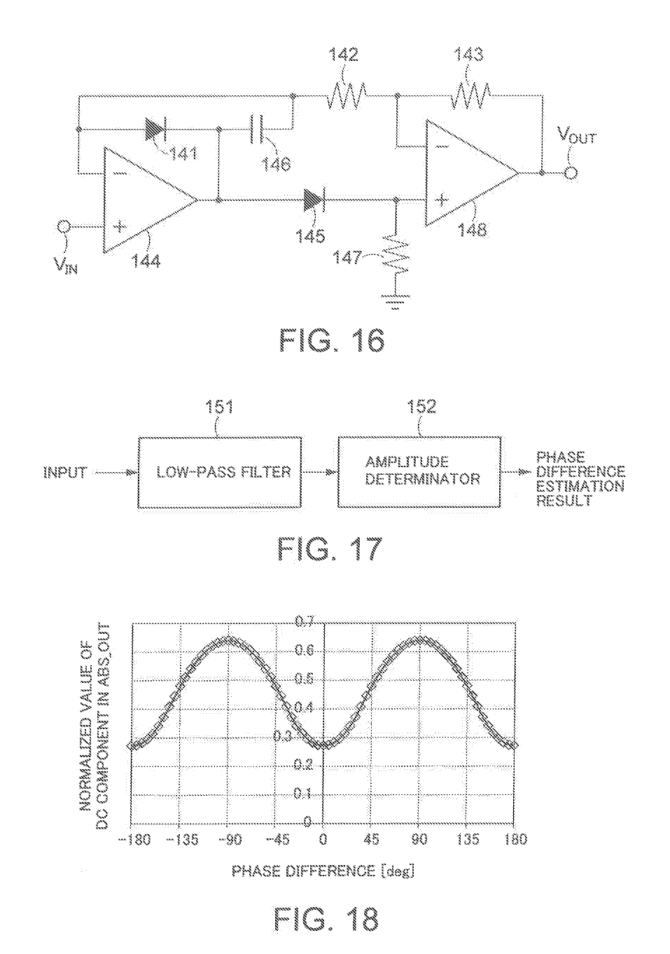

The absolute value detectors illustrated in FIG. 3 and FIG. 15 can be formed using, for example, an analog circuit illustrated in FIG. 16. This analog circuit includes diodes 141 and 145, resistors 142, 143, and 147, a capacitor 146, and comparators 144 and 145, generates, using these elements, an absolute value signal that represents an absolute value of a signal input into a terminal Vᵢₙ, and outputs the absolute value signal from a terminal Vₒᵤₜ.

As seen from the above, according to the present embodiment, AC components are detected from an input current of an inverter, and in accordance with an amplitude of a second-harmonic frequency component of a fundamental in an absolute value signal of the AC components, a phase relation between output voltage and output current of the inverter is estimated. As with the related art described in the section of BACKGROUND, in a case of observing current on an output side of an inverter, it is difficult to secure a detection precision of the current due to steep fluctuations of voltage. However, since an input voltage of the inverter is constant, occurrence of such a problem is suppressed in the present embodiment. In addition, in the present embodiment, since voltage need not be detected for estimating the phase difference, there arises no problem of difference in frequency properties between current detecting means and voltage detecting means that occurs in the case of using both of the current detecting means and the voltage detecting means as with the related art.

### Second Embodiment

A block diagram of a voltage converting device according to a second embodiment is the same as that illustrated in FIG. 3, but the configuration of the phase difference estimator 108 differs. While use is made of the second-harmonic frequency of the fundamental in the output the absolute value detector 107 as the specific frequency component in the first embodiment, the DC component is used in the second embodiment. FIG. 17 illustrates a configuration of a phase difference estimator 108 according to the second embodiment. The phase difference estimator 108 illustrated in FIG. 17 includes a low-pass filter 151 and an amplitude determinator 152. The low-pass filter 151 is configured to extract, from the absolute value signal that is the output of the absolute value detector 107, its low-frequency component (DC component) of the absolute value signal. That is, the low-pass filter 151 operates in such a manner as to cut off components having frequencies higher than the second-harmonic frequency of the fundamental. The amplitude determinator 152 is configured to estimate the phase difference in accordance with an amplitude of the DC component. The estimation method is the same as that in the first embodiment.

In FIG. 12 described before, focusing on the DC component, it can be confirmed that the value of the DC component significantly varies between a phase difference of 0 degrees and a phase difference of 90 degrees. Therefore, if is considered that utilizing this also enables the detection of the phase difference as in the first embodiment. FIG. 18 illustrates a relation between the magnitude of the DC component in ABS_OUT (the output waveform of the absolute value detector 107) and the phase difference. From FIG. 18, the DC component in ABS_OUT (the output waveform of the absolute value detector 107) has the same dependency on the phase difference as that of the second-harmonic frequency component of the fundamental illustrated in FIG. 13. Therefore, the phase difference can be estimated by applying the various methods described in the first embodiment in the same manner. The detection of the phase difference can be similarly implemented with not only the DC component and the second-harmonic frequency component but also another frequency, as long as the value of the frequency component significantly varies at a plurality of phase differences.

### Third Embodiment

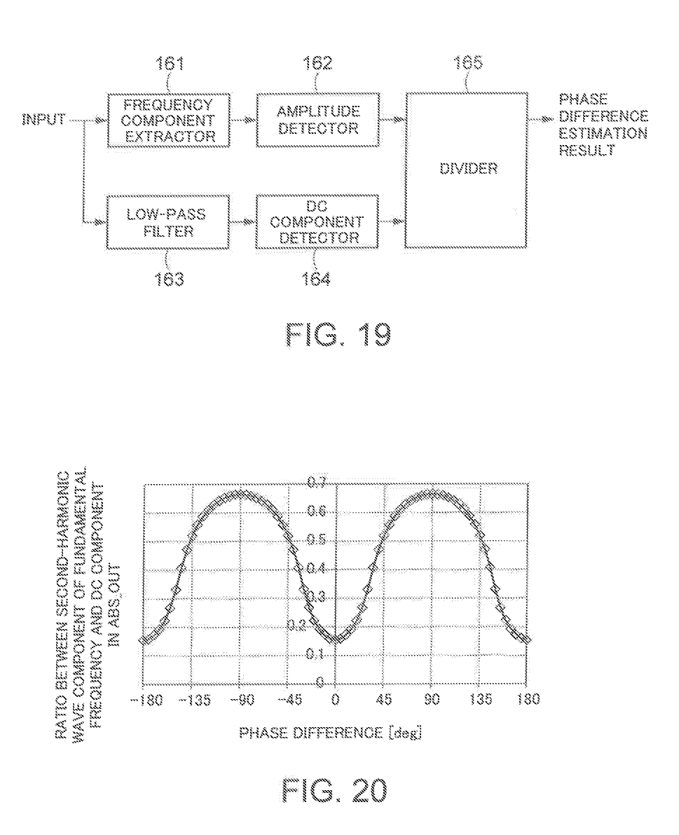

A third embodiment will be described. A block diagram of a voltage converting device according to the third embodiment is the same as that illustrated in FIG. 3, but the configuration of the phase difference estimator 108 differs. While use is made of the second-harmonic frequency of the fundamental in the output of the absolute value detector 107 in the first embodiment, use is made of a ratio between the second-harmonic wave component and the DC component, of the fundamental, in the present embodiment. FIG. 19 is a diagram illustrating the configuration of the phase difference estimator according to the third embodiment.

The phase difference estimator illustrated in FIG. 19 includes a frequency component extractor 161, an amplitude detector 162, a low-pass filter 163, a DC component detector 164, and a divider 165. The frequency component extractor 161 is configured to extract the second-harmonic frequency component from ABS_OUT (the output waveform of the absolute value detector). The amplitude detector 162 is configured to detect an amplitude value of the second-harmonic frequency component. The low-pass filter 163 is configured to cut off frequencies higher than the second-harmonic frequency of the fundamental, from ABS_OUT (the output waveform of the absolute value detector). The DC component detector 164 is configured to detect the value of the DC component from a signal that passes the low-pass filter 163. The divider 165 is configured to calculate a ratio between a value of the amplitude detected by the amplitude detector 162 and the value of the DC component detected by the DC component detector 164. For example, by dividing the amplitude value of the second-harmonic frequency component of the fundamental by the value of the DC component, the ratio is calculated. Then, using the calculated ratio, a phase relation such as the phase difference is estimated as in the embodiments described thus fan such as the use of the threshold values or the look-up table.

FIG. 20 illustrates a relation between the ratio between the amplitude value of the second-harmonic frequency component and the value of the DC component, of the fundamental in ABS_OUT (the output waveform of the absolute value detector 107), and the phase difference. Since the DC component and the second-harmonic frequency component are both proportional to a current amplitude, the ratio of these value is determined from only the phase difference irrespective of a magnitude of the current. Therefore, even in a case where a current value significantly varies, the same configuration for phase determination can be used. That is, irrespective of the magnitude of the current, it is possible to estimate the phase difference with high precision by referring the same threshold values, the same look-up table, or the like.

### Fourth Embodiment

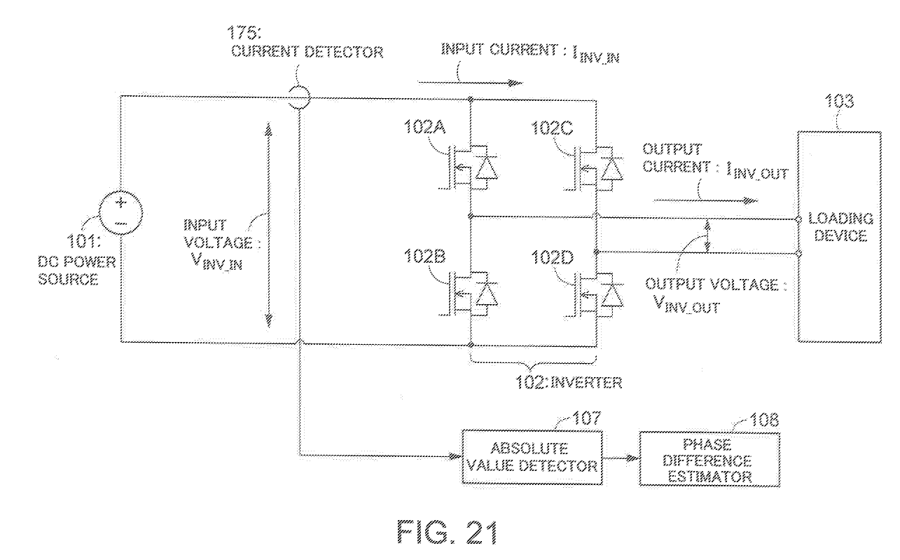

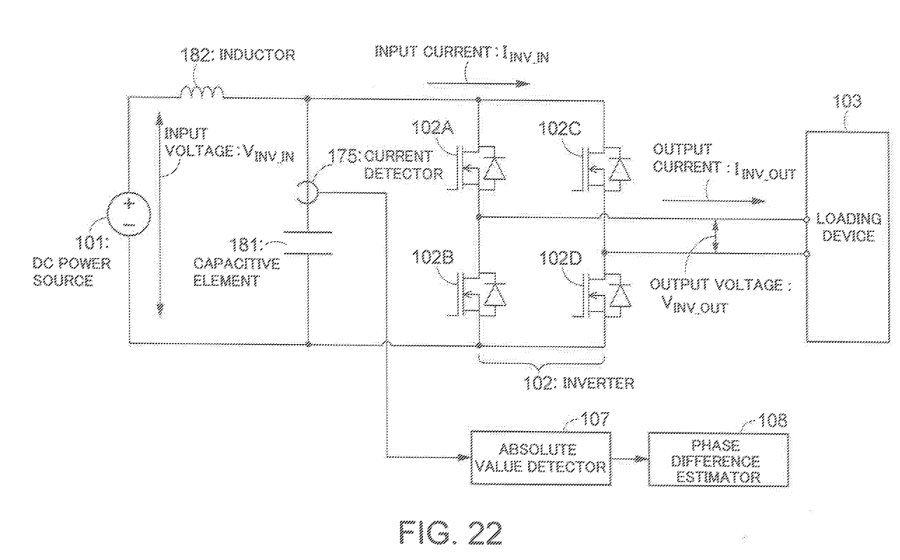

FIG. 21 illustrates a configuration of a voltage converting device according to a fourth embodiment. What differs from the first embodiment is that the high-pass filter is eliminated. Furthermore, in the fourth embodiment, use is made of a sensor having no sensitivity to DC in a current detector 175. In general, some current sensors such as a current transformer (CT) have no sensitivity to DC components in accordance with applications. Therefore, by using such a current sensor, the high-pass filter can be dispensed with. The absolute value detector 107 may generate an absolute value signal that represents an absolute value of a current (AC component) signal detected by the current detector 175.

### Fifth Embodiment

FIG. 22 illustrates a configuration of a voltage converting device according to a fifth embodiment. What differs from the first embodiment is that an inductor 182 and a capacitive element 181 are provided on the output side of the DC power source 101. The inductor 182 is connected to the DC power source 101 in series, and the capacitive element 181 is connected to the DC power source 101 in parallel. In addition, the current detector 105 detects current through the capacitive element 181, and the high-pass filter is eliminated. The inductor 182 may be a real inductor element, or a parasitic inductance of a wire may be used as the inductor 182.

In the fifth embodiment, by configuring the voltage converting device in such a manner that the capacitive element 181 has lower impedances than the inductor 182 to components having frequencies higher than the second-harmonic frequency of the fundamental, AC components of an inverter input current are supplied from the capacitive element 181, and a DC component of the inverter input current is supplied from an inductor 182 side. This allows only the AC components of the inverter input current to be detected by detecting the current through the capacitive element 181. Therefore, the high-pass filter is dispensed with.

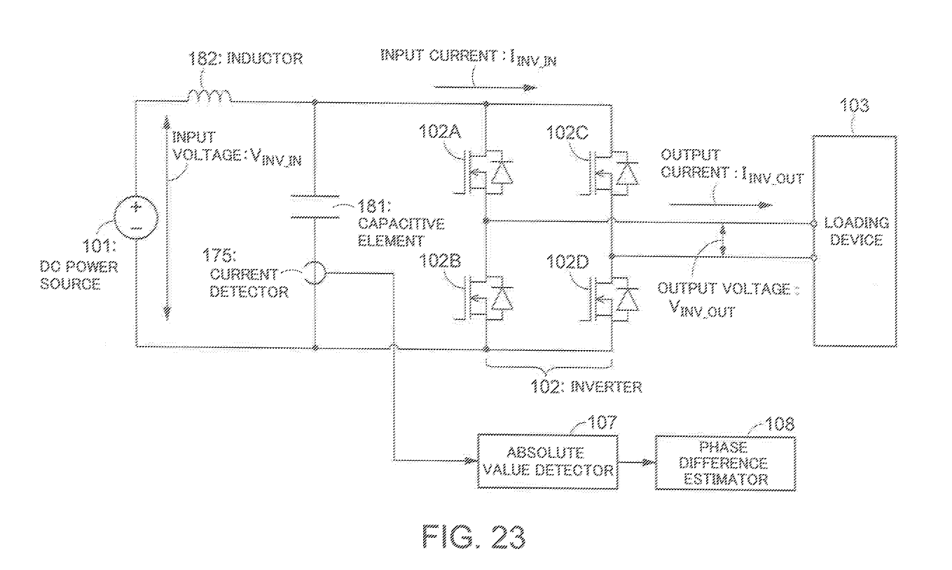

As another configuration, current may be observed at a terminal of the capacitive element 181 connected to a negative-side of the DC power source 101, using a current detector 175, as illustrated in FIG. 23. In a case where ripple voltages occur at both ends of the capacitive element 181 due to an influence of an inductance of the inductor 182, when amounts of ripples differ between both ends of the capacitive element 181, the influence can be reduced by detecting the current at a terminal having a smaller one of the amounts of ripples (a terminal on the negative-side of the DC power source 101 to which the inductor is not connected).

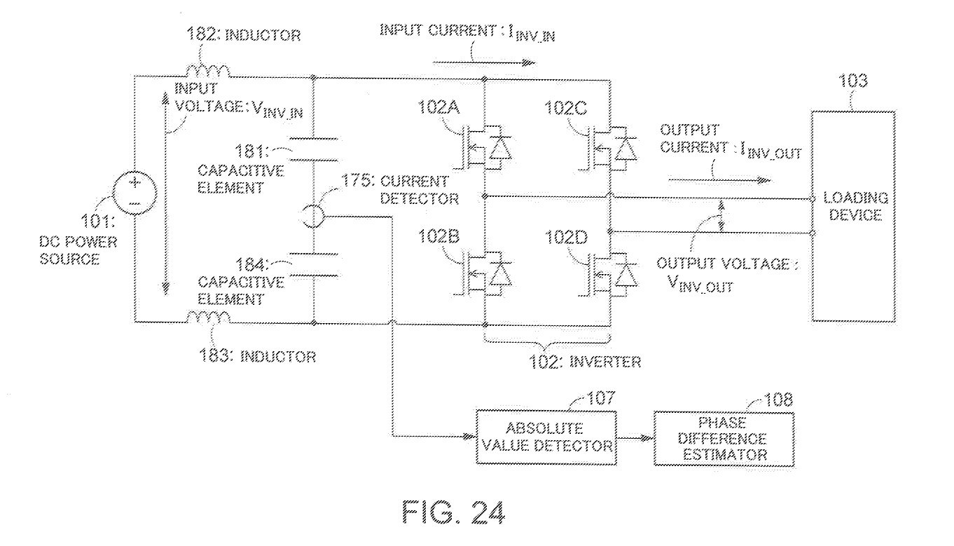

As still another configuration, an inductor 183 is connected to the negative-side of the DC power source 101 in series, and two capacitive elements 181 and 184 are connected to the DC power source 101 in parallel, as illustrated in FIG. 24. The current detector 105 observes current at, for example, a middle point between the capacitive elements 181 and 184. In a case where inductances are added on positive and negative sides symmetrically, the influence of the ripples can be reduced by observing the current at a position that is a middle point in terms of potential.

### Sixth Embodiment

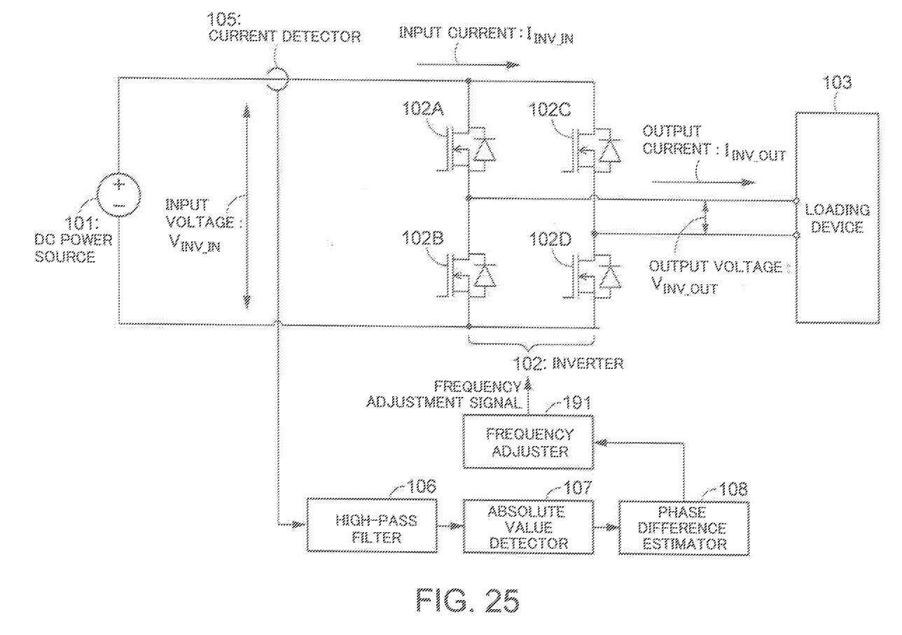

FIG. 25 illustrates a configuration of a voltage converting device according to a sixth embodiment. In the configuration illustrated in FIG. 25, a frequency adjuster 191 is added to the configuration illustrated in FIG. 3.

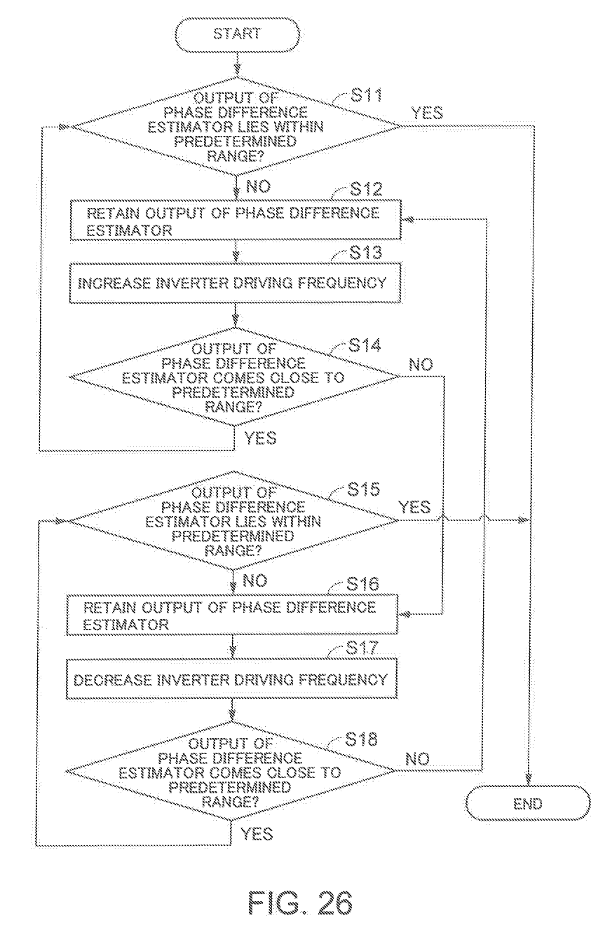

The frequency adjuster 191 is configured to generate, based on an output (estimation result) of the phase difference estimator 108, a frequency adjustment signal to adjust a driving frequency of the inverter 102 so as to bring the phase relation close to a desired relation (e.g., bring the phase difference close to a desired value). The frequency adjuster 191 is configured to output the generated frequency adjustment signal to the driving device for the inverter 102. The driving device of the inverter 102 controls a switching timing of each switching element in accordance with the frequency adjustment signal, so as to control a frequency of an output current. For example, to bring the phase difference closer to zero, the frequency adjuster 191 may generate the adjusting signal so that an output of the phase difference estimator shows a value close to a phase difference of zero. As an example, by following an operation flow example illustrated in FIG. 26, it is possible to bring the output of the phase difference estimator close to a predetermined range and within the predetermined range.

First, whether an output of the phase difference estimator 108 lies within the predetermined range is determined (S11). The predetermined range is a range that the output of the phase difference estimator 108 can take when the phase difference lies within an intended range. If the output lies within the predetermined range, a frequency changing operation is terminated. If the output lies out of the predetermined range, the output of the phase difference estimator 108 is retained in a storage device such as a memory (S12), and a driving frequency of the inverter is increased (S13). The storage device may be provided inside the phase difference estimator 108 or outside the phase difference estimator 108. After increasing the frequency, whether the output of the phase difference estimator 108 comes closer to the predetermined range than the value previously retained is determined (S14). If the output comes closer to the predetermined range, the same operation is repeated.

On the other hand, if the output does not come closer to the predetermined range, that is, grows distant from the predetermined range, the output of the phase difference estimator is retained in the storage device such as a memory, and the driving frequency of the inverter is decreased (S17). Thereafter, whether the output of the phase difference estimator 108 comes closer to the predetermined range is determined again (S18), and if the output comes closer to the predetermined range, the same process is repeated. If the output grows distant from the predetermined range, the output of the phase difference estimator is retained (S12), and the driving frequency of the inverter is increased (S13).

An increasing change width to increase the driving frequency of the inverter in step S13 and a decreasing change width to decrease the driving frequency of the inverter in step S17 may be a constant width. Alternatively, the increasing change width, the decreasing change width, or both of these may be varied in accordance with an output value of the phase difference estimator 108.

By repeating the above process, it is possible to adjust the driving frequency of the inverter so that the phase difference lies within a desired range. While the output of the phase difference estimator is controlled to lie within the predetermined range in the above operation flow, the output may be controlled to agree with the predetermined value. In this case, in the description of the above operation flow, the predetermined range may be replaced by the predetermined value, and in step S11, whether the output agrees with the predetermined value may be determined.

Since the fundamental frequency varies when the driving frequency of the inverter is changed, frequency properties of various filtering units may be set appropriately with an amount of the change factored in. Alternatively, the frequency properties of the various filtering units may be switched in accordance with the change of the driving frequency of the inverter.

In a case where determination can be made uniquely in advance as to whether to increase or decrease the frequency so as to bring the output of the phase difference estimator 108 close to the desired range or the predetermined value, such as a case where a frequency characteristics of an impedance of the loading device 103 is known, the frequency may be changed based on the determination. In a case of following the operation flow example illustrated in FIG. 26, the output of the phase difference estimator 108 can be made to lie within the predetermined range even when whether such a frequency should be moved in an increasing direction or a decreasing direction is unknown.

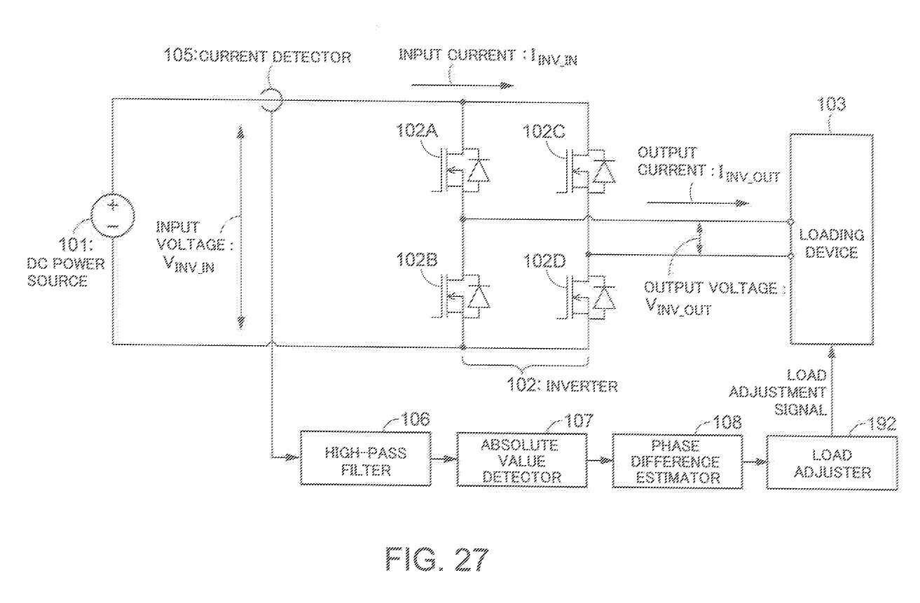

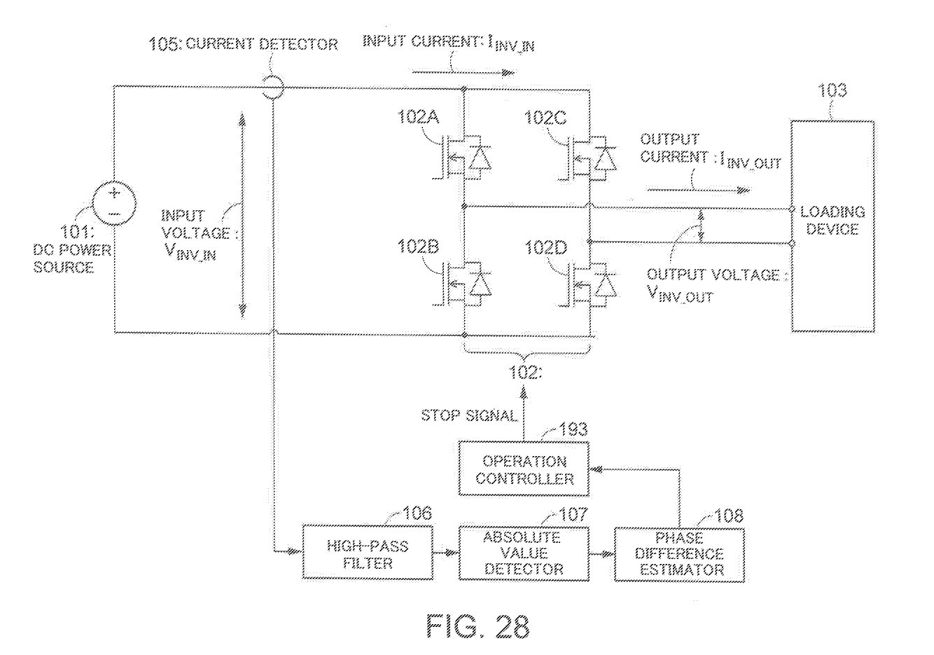

FIG. 27 illustrates another configuration example of the voltage converting device according to the sixth embodiment. What differs from the configuration illustrated in FIG. 25 is in that a load adjuster 192 is provided in place of the frequency adjuster. The load adjuster 192 is configured to perform load adjustment to change a phase of the output current. The load adjustment is performed by, for example, changing an element value of a variable element such as a variable capacitance, a variable inductance, and a variable resistor provided in the loading device 103, and is equivalent to adjusting a frequency characteristics of the loading device. As an operation flow of the load adjuster 192, a value that is obtained by converting the frequency changed in steps S13 and S17 of the operation flow illustrated in FIG. 26 into the element value of the variable element in the loading device 103 can be applied.

In a case where the voltage converting device is applied to a wireless power transmitting device, the load adjuster 192 may be present on a power transmitting device side or may be present on a power receiving device side. In a case where the load adjuster 192 is present on the power transmitting device side, a load adjustment signal is sent to a power receiving device through wireless or wired communication, and the load adjustment signal is received on the power receiving device side and output to the loading device 103. In a case where the load adjuster 192 is present on the power receiving device side, the output of the phase difference estimator is sent from the power transmitting device to the power receiving device through wireless communication, and the load adjuster 192 on the power reception side may generate a load adjustment signal based on the output of the phase difference estimator. A scheme of the wireless communication may be compliant with a common wireless communication standard such as a wireless LAN and Bluetooth®, or a proprietary wireless communication standard.

As another example of a method for the load adjustment, in a case where coupled coils (Lₜₓ and Lᵣₓ) are present as with the wireless power transmitting device illustrated in FIG. 1, a state of the coupling may be adjusted. For a wireless power transmitting device, it is generally known that an impedance varies by changing a state of coupling between coils. Therefore, by changing a physical positional relation between the power transmitting coil (Lₜₓ) and the power receiving coil (Lᵣₓ), it is possible to perform adjustment that makes the output of the phase difference estimator 108 lie within the predetermined range or agree with the predetermined value. Adjusting a frequency characteristics of the coil unit on the power transmission side, adjusting a frequency characteristics of the coil unit on the power reception side, and adjusting a load connected to the power receiving device are also included in the load adjustment. Adjusting the frequency characteristics of the coil unit on the power transmission side includes, for example, changing element values of the coil Cₜₓ, the inductor Lₜₓ, and the like. Adjusting the frequency characteristics of the coil unit on the power reception side includes, for example, changing element values of the coil Cᵣₓ, the inductor Lᵣₓ, and the like. Adjusting the load connected to the power receiving device includes changing an element value of the resistor R.

### Seventh Embodiment

FIG. 28 illustrates a configuration of a voltage converting device according to a seventh embodiment. The configuration illustrated in FIG. 28 includes, in addition to the configuration illustrated in FIG. 3, an operation controller 193. The operation controller 193 is configured to output a stop signal in accordance with the output of the phase difference estimator 108. For example, in a case where the phase difference lies out of the predetermined range in the phase difference estimator 108, the operation controller 193 outputs the stop signal to the driving device of the inverter 102. Upon receiving the stop signal, the driving device of the inverter 102 stops operation of the AC power supply. By setting the predetermined range appropriately, it is possible to stop the operation of the AC power supply in a case where the loading device 103 is brought into an unexpected state or an abnormal state. After the stop, an appropriate operation such as notifying the stop to a monitoring device with some means, resuming the operation again from an initial state, performing check, calibration, or the like of the loading device 103, may be selected. For example, in the wireless power transmitting device, if a possible range of the output of the phase difference estimator in the positional relation between the power transmitting coil and the power receiving coil in a power transmittable state is enabled is known, by detecting that the output of the phase difference estimator lies out of the predetermined range, it is possible to sense that the positional relation between the power transmitting coil and the power receiving coil is a positional relation with which the power transmission is disabled, and to stop the operation of the AC power supply.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A voltage converting device, comprising:
a DC power source configured to generate direct-current voltage;
an inverter including a first terminal electrically connected to one of a positive-side terminal and a negative-side terminal of the DC power source and including a second terminal electrically connected to another one of the positive-side terminal and the negative-side terminal, the inverter being configured to generate AC power based on the direct-current voltage;
an AC component detector configured to detect an AC component of current flowing through the first terminal or the second terminal; and
a phase estimator configured to estimate a phase relation between a phase of voltage of the AC power and a phase of current of the AC power based on an amplitude of a specific frequency component contained in a first absolute value signal of the AC component, wherein
the AC power generated by the inverter is supplied to a loading device, and
an impedance of the loading device at a fundamental of a driving frequency of the inverter is smaller than an impedance of the loading device at an odd-order harmonic of the driving frequency.

2. The voltage converting device according to claim 1, further comprising
a capacitive element including one end electrically connected to one of terminals of the DC power source and including another end electrically connected to another one of the terminals of the DC power source, wherein
the AC component detector detects current flowing through the capacitive element, as the AC component.

3. The voltage converting device according to claim 1, wherein the AC component detector includes a current detector configured to detect current flowing through the first terminal or the second terminal and includes a filter configured to extract an AC component from the current detected by the current detector.

4. The voltage converting device according to claim 1, wherein the AC component detector detects the AC component using a current sensor having no sensitivity to direct current.

5. The voltage converting device according to claim 1, wherein the specific frequency component is a component having a frequency twice the driving frequency of the inverter.

6. The voltage converting device according to claim 1, wherein the phase estimator generates a second absolute value signal that represents an absolute value of the specific frequency component, extracts a DC component from the second absolute value signal using a low-pass filter, and estimates the phase relation based on the DC component.

7. The voltage converting device according to claim 1, wherein the phase estimator extracts a DC component from the first absolute value signal using a low-pass filter, detects a value of the DC component, and estimates the phase relation based on a ratio between an amplitude value of the specific frequency component contained in the first absolute value signal and a value of the DC component.

8. The voltage converting device according to claim 1, further comprising a frequency adjuster configured to adjust the driving frequency of the inverter so that a phase difference between the voltage and the current lies within a predetermined range.

9. The voltage converting device according to claim 1, further comprising a load adjuster configured to adjust a frequency characteristics of the loading device so that a phase difference between the voltage end the current lies within a predetermined range.

10. The voltage converting device according to claim further comprising an operation controller configured to output a stop signal to stop operation of the inverter when a phase difference between the voltage and the current lies out of a predetermined range.

11. The voltage converting device according to claim 1, further comprising an absolute value detector configured to generate the first absolute value signal based on the AC component detected by the AC component detector.

12. The voltage converting device according to claim 1, further comprising
a filter configured to extract the specific frequency component from the first absolute value signal, wherein
the filter is one of a band-pass filter, a low-pass filter, and a high-pass filter.

13. A wireless power transmitting device, comprising:
a DC power source configured to generate direct-current voltage;
an inverter including a first terminal electrically connected to one of a positive-side terminal and a negative-side terminal of the DC power source and including a second terminal electrically connected to another one of the positive-side terminal and the negative-side terminal, the inverter being configured to generate AC power based on the direct-current voltage;
an AC component detector configured to detect an AC component of current flowing through the first terminal or the second terminal; and
a phase estimator configured to estimate a phase relation between a phase of voltage of the AC power and a phase of current of the AC power based on an amplitude of a specific frequency component contained in a first absolute value signal of the AC component, wherein
the AC power generated by the inverter is supplied to a loading device, and an impedance of the loading device at a fundamental of a driving frequency of the inverter is smaller than an impedance of the loading device at an odd-order harmonic of the driving frequency, and
the loading device includes a coil unit including a power transmitting coil and transmits the AC power generated by the inverter to a power receiving coil of a power receiving device through a magnetic coupling.

14. The wireless power transmitting device according to claim 13, wherein the wireless power transmitting device controls at least one of the driving frequency of the inverter, a frequency characteristics of the coil unit, a frequency characteristics of the power receiving device, and a positional relation between the power transmitting coil and the power receiving coil so that a phase difference between the voltage and the current is reduced.
